(19) United States
(12) Patent Application Publication
(10) Pub. No.: US 2026/0096486 A1
(43) Pub. Date: Apr. 2, 2026

(54) SEMICONDUCTOR PACKAGE

(71) Applicant: Samsung Electronics Co., Ltd., Suwon-si (KR)

(72) Inventors: Chajea JO, Suwon-si (KR); Yuna KIM, Suwon-si (KR); Jongyong KIM, Suwon-si (KR)

(73) Assignee: Samsung Electronics Co., Ltd., Suwon-si (KR)

(21) Appl. No.: 19/251,073

(22) Filed: Jun. 26, 2025

(30) Foreign Application Priority Data
Sep. 30, 2024 (KR) 10-2024-0133130

(51) Int. Cl. H01L 25/16; H01L 23/00; H01L 23/31; H01L 23/522

(52) U.S. Cl. CPC H10W 90/00; H10W 20/42; H10W 74/111; H10W 90/722

(57) ABSTRACT

A semiconductor package may include a first semiconductor chip having a first thickness, a second semiconductor chip including a plurality of chiplet dies on the first semiconductor chip, and a molding member covering the plurality of chiplet dies. At least one of the plurality of chiplet dies may have a second thickness greater than the first thickness. The plurality of chiplet dies may be spaced apart from each other in a horizontal direction to form gaps between the chiplet dies. The molding member may have a coefficient of thermal expansion higher than a coefficient of thermal expansion for the first semiconductor chip and a coefficient of thermal expansion for the plurality of chiplet dies. The molding member may include extension portions that fill the gaps.

### PRIORITY STATEMENT

This application claims priority under 35 U.S.C. § 119 to Korean Patent Application No. 10-2024-0133130, filed on Sep. 30, 2024, in the Korean Intellectual Property Office (KIPO), the contents of which are herein incorporated by reference in their entirety.

### BACKGROUND

### 1. Field

Example embodiments relate to a semiconductor package. More particularly, example embodiments relate to a semiconductor package including different types of semiconductor devices.

### 2. Description of the Related Art

A semiconductor package including different types of semiconductor devices may have a structure in which one semiconductor device having a relatively thin thickness may be stacked on another semiconductor device or a package substrate having a relatively thick thickness. In this case, warpage may occur due to differences between thermal expansion coefficients and/or structural characteristics of the semiconductor devices. Particularly, since the semiconductor devices may be heated to a high temperature and cooled during a process of connecting the semiconductor devices, warpage may occur from the thicker semiconductor device toward the thinner semiconductor device. Further, the warpage may cause defects when the semiconductor package is connected to a printed circuit board (PCB) or the like.

### SUMMARY

Example embodiments provide a semiconductor package including a molding member capable of limiting and/or preventing warpage of the semiconductor package.

According to some example embodiments, a semiconductor package may include a lower semiconductor chip; an upper semiconductor chip on the lower semiconductor chip, the upper semiconductor chip having a first chiplet die, a second chiplet die, and a third chiplet die spaced apart from each other in a first horizontal direction; and a molding member on the lower semiconductor chip and covering the upper semiconductor chip. A thickness of at least one of the first chiplet die, the second chiplet die, and the third chiplet die may be greater than a thickness of the lower semiconductor chip. A coefficient of thermal expansion of the molding member may be greater than a coefficient of thermal expansion of the lower semiconductor chip. A first extension portion of the molding member may fill a first gap between the first chiplet die and the second chiplet die. A second extension portion of the molding member may fill a second gap between the second chiplet die and the third chiplet die.

According to some example embodiments, a semiconductor package may include a first semiconductor chip including a first substrate and a first wiring layer on the first substrate; a second semiconductor chip including a first chiplet die mounted on the first semiconductor chip via a plurality of first conductive connection members, a second chiplet die mounted on the first semiconductor chip via a plurality of second conductive connection members, and a third chiplet die mounted on the first semiconductor chip via a plurality of third conductive connection members, wherein the first chiplet die, the second chiplet die, and the third chiplet die may be spaced apart from each other in a first horizontal direction to define a first gap between the first chiplet die and the second chiplet die and to define a second gap between the second chiplet die and the third chiplet die; and a molding member on the first semiconductor chip and covering the first chiplet die, the second chiplet die, and the third chiplet die. A distance in a vertical direction between a lower surface of the first substrate and a highest one of an upper surface of the first chiplet die, an upper surface of the second chiplet die, and an upper surface of the third chiplet die may have a first height. The plurality of first conductive connection members, the plurality of second conductive connection members, and the plurality of third conductive connection members may be below a central extension line passing through a center of the first height. A coefficient of thermal expansion of the molding member may be greater than a coefficient of thermal expansion of the first semiconductor chip. A first extension portion of the molding member may fill the first gap. A second extension portion of the molding member may fill the second gap.

According to some example embodiments, a semiconductor package may include a first semiconductor chip; at least one chiplet die mounted on the first semiconductor chip; a first chip structure on the first semiconductor chip, the first chip structure being spaced apart from the at least one chiplet die in a first horizontal direction to define a first gap between the first chip structure and the at least one chiplet die; a second chip structure on the first semiconductor chip, the second chip structure being spaced apart from the at least one chiplet die and the first chip structure in the first horizontal direction to define a second gap between the second chip structure and the first chip structure; and a molding member on the first semiconductor chip and covering the at least one chiplet die, the first chip structure, and the second chip structure. A thickness of at least one of the at least one chiplet die, the first chip structure, and the second chip structure may be greater than a thickness of the first semiconductor chip; A coefficient of thermal expansion of the molding member may be greater than a coefficient of thermal expansion of the first semiconductor chip. A first extension portion of the molding member may fill the first gap, and a second extension portion of the molding member may fill the second gap.

According to example embodiments, a semiconductor package may include a first semiconductor chip having a first thickness, a second semiconductor chip including a plurality of chiplet dies mounted on the first semiconductor chip, and a molding member covering the plurality of chiplet dies. At least one of the plurality of chiplet dies may have a second thickness greater than the first thickness.

The plurality of chiplet dies may be spaced apart from each other in a horizontal direction to form gaps between adjacent ones of the plurality of chiplet dies. The molding member may have a relatively high coefficient of thermal expansion, and the molding member may have extension portions that fills the gaps.

Accordingly, each of the extension portions of the molding member may have a relatively high coefficient of thermal expansion, so the molding member may shrink upon cooling. Thus, each of the extension portions of the molding member may generate a force in the direction in which the plurality of chiplet dies come closer to each other, to thereby reduce or prevent warpage of the semiconductor package.

According to some example embodiments, a method of manufacturing a semiconductor package may include providing a wafer, the wafer including a wiring layer on a substrate, and the wafer including a plurality of die regions and a scribe lane region surrounding the plurality of die regions; mounting a plurality of chiplet dies on the wiring layer of a die region among the plurality of die regions of the wafer, wherein the plurality of chiplet dies may include a first chiplet die, a second chiplet die, and a third chiplet die spaced apart from each other in a first horizontal direction; and forming a molding layer covering the wafer and the plurality of chiplet dies; and forming an upper semiconductor chip on a lower semiconductor chip by separating the die region from the wafer and separating a molding member from the molding layer. The molding member may surround the first chiplet die, the second chiplet die, and the third chiplet die. The upper semiconductor chip may include the molding member, the first chiplet die, the second chiplet die, and the third chiplet die. A thickness of at least one of the first chiplet die, the second chiplet die, and the third chiplet die may be greater than a thickness of the lower semiconductor chip. A coefficient of thermal expansion of the molding member may be greater than a coefficient of thermal expansion of the lower semiconductor chip. A first extension portion of the molding member may fill a first gap between the first chiplet die and the second chiplet die. A second extension portion of the molding member may fill a second gap between the second chiplet die and the third chiplet die.

In some embodiments, the first chiplet die may have a first thickness, the second chiplet die may have a second thickness, and the third chiplet die may have a third thickness. The first thickness, the second thickness, and the third thickness may be equal to each other, or the second thickness and the third thickness may be less than the first thickness.

In some embodiments, the first extension portion may be in contact with a side surface of the first chiplet die and a side surface of the second chiplet die, respectively.

In some embodiments, the second extension portion may be in contact with a side surface of the second chiplet die and a side surface of the third chiplet die, respectively.

In some embodiments, the second chiplet die may be between the first chiplet die and the third chiplet die.

### BRIEF DESCRIPTION OF THE DRAWINGS

FIG. 1 is a cross-sectional view illustrating a semiconductor package in accordance with example embodiments.

FIG. 2 is a plan view illustrating the semiconductor package in FIG. 1.

FIG. 3 is a cross-sectional view illustrating the semiconductor package in FIG. 1 mounted on an external device.

FIGS. 4 to 11 are views illustrating a method of manufacturing a semiconductor package in accordance with example embodiments.

FIG. 12 is a cross-sectional view illustrating a semiconductor package in accordance with example embodiments.

FIG. 13 is a plan view illustrating the semiconductor package in FIG. 12.

FIG. 14 is a cross-sectional view illustrating a semiconductor package in accordance with example embodiments.

FIG. 15 is a plan view illustrating the semiconductor package in FIG. 14.

FIG. 16 is a cross-sectional view illustrating a semiconductor package in accordance with example embodiments.

FIG. 17 is a plan view illustrating the semiconductor package in FIG. 16.

FIG. 18 is a cross-sectional view illustrating a semiconductor package in accordance with example embodiments.

FIG. 19 is a cross-sectional view taken along the line C6-C6′ in FIG. 18.

FIG. 20 is a cross-sectional view taken along the line C6-C6′ in FIG. 18.

FIG. 21 is a cross-sectional view illustrating a semiconductor package in accordance with example embodiments.

### DETAILED DESCRIPTION OF EXAMPLE EMBODIMENTS

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, example embodiments will be explained in detail with reference to the accompanying drawings.

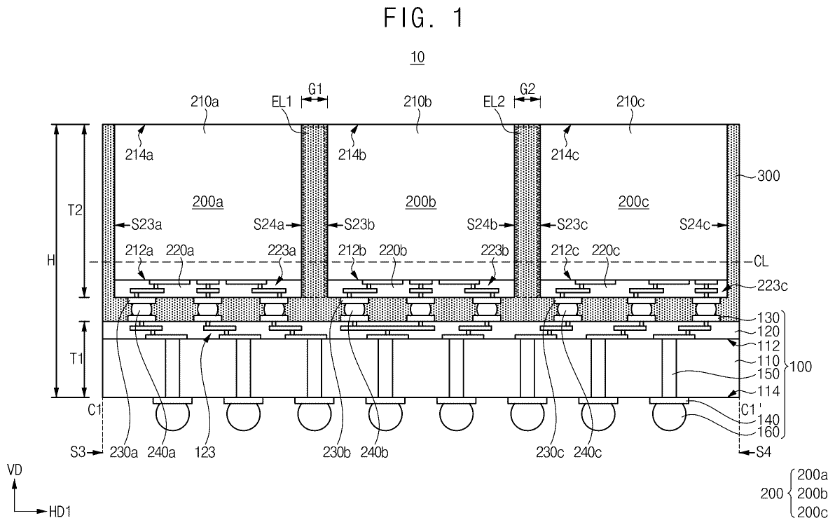

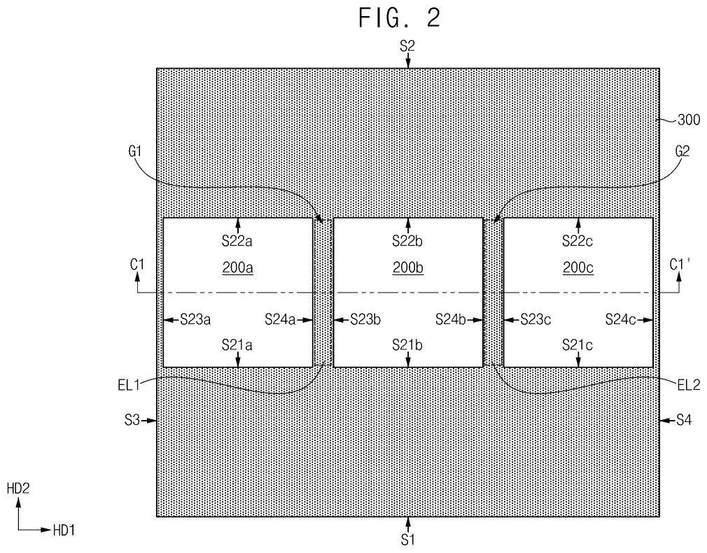

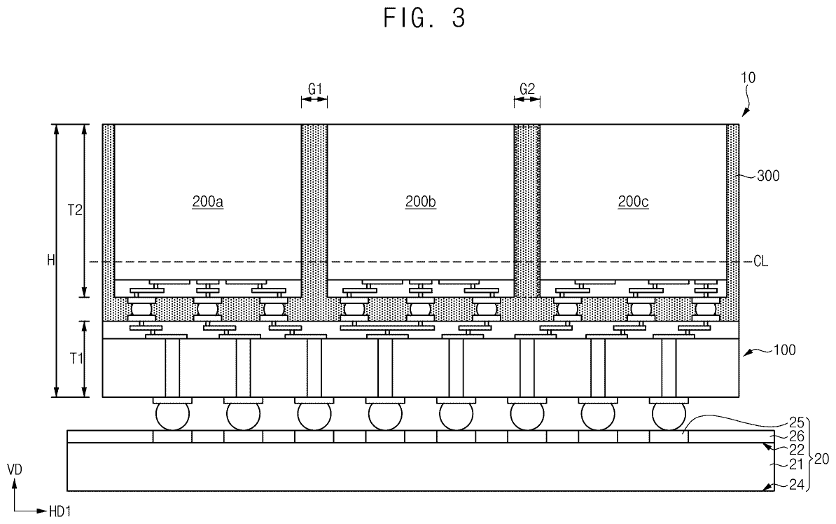

FIG. 1 is a cross-sectional view illustrating a semiconductor package in accordance with example embodiments. FIG. 2 is a plan view illustrating the semiconductor package in FIG. 1. FIG. 3 is a cross-sectional view illustrating the semiconductor package in FIG. 1 mounted on an external device. FIG. 1 is a cross-sectional view taken along the line C1-C1′ in FIG. 2.

Referring to FIGS. 1 to 3, a semiconductor package 10 may include a first semiconductor chip 100 (e.g., lower semiconductor chip), a second semiconductor chip 200 (e.g., upper semiconductor chip) mounted on the first semiconductor chip 100 and including first, second and third chiplet dies 200a, 200b, 200c, and a molding member 300 provided on the first semiconductor chip 100 to covers the second semiconductor chip 200. The semiconductor package 10 may further include a plurality of external connection members 160 and a plurality of first, second and third conductive connection members 240a, 240b, and 240c.

In example embodiments, the first semiconductor chip 100 may include a first substrate 110 having a first surface 112 and a second surface 114 facing away from (e.g., opposite) the first surface 112, a first wiring layer 120 provided on the first surface 112 of the first substrate 110, a plurality of first pads 130 provided on the first wiring layer 120, and a plurality of second pads 140 provided on the second surface 114 of the first substrate 110. The first semiconductor chip 100 may further include a plurality of first through vias 150 that penetrate the first substrate 110. The first semiconductor chip 100 may further include a plurality of external connection members 160 respectively provided on the plurality of second pads 140. For example, the plurality of external connection members 160 may include a conductive metallic material and may electrically connect the semiconductor package 10 to an external device, such as a printed circuit board (PCB), an interposer, or the like.

For example, the first semiconductor chip may include a logic chip having logic circuitry. Alternatively, the semiconductor chip may include a volatile memory device, such as DRAM, or a non-volatile memory device, such as NAND flash memory.

The first substrate 110 may have a first surface 112 as an active surface and a second surface 114 as an inactive surface. The first surface and the second surface may extend in a first horizontal direction HD1 and a second horizontal direction HD2 perpendicular to the first horizontal direction HD1, respectively. The first substrate 110 may have a first side portion S1 and a second side portion S2 extending in the first horizontal direction HD1, and a third side portion S3 and a fourth side portion S4 extending in the second horizontal direction HD2. For example, the first substrate may have a square shape when viewed in plan view. The first substrate may include silicon (Si).

The first wiring layer 120 may include a plurality of first wirings 123 and an insulation layer covering the plurality of first wirings 123.

The plurality of first pads 130 may be electrically connected with the plurality of first wirings 123. The plurality of first pads 130 may be provided on the first wiring layer 120 such that the plurality of first pads 130 are arranged in the first horizontal direction HD1 and the second horizontal direction HD2, respectively. For example, the plurality of first pads may include a conductive metallic material.

The plurality of second pads 140 may be provided on the second surface 114 of the first substrate 110 such that the plurality of second pads 140 are arranged in the first horizontal direction HD1 and the second horizontal direction HD2, respectively. For example, the plurality of second pads may include a conductive metallic material.

While only a few pads are illustrated in the figures, it will be understood that the number, shape, and arrangement of the plurality of first and second pads are provided as an example, so the present inventive concept is not limited thereto.

Each of the plurality of first through vias 150 may penetrate the first substrate 110 to electrically connect the plurality of first wirings 123 of the first wiring layer 120 and the plurality of second pads 140. For example, the plurality of first through vias may include a conductive metallic material.

Although only a few through vias are illustrated in the figures, it will be understood that the number, shape, and arrangement of the through vias are provided as an example so the present inventive concept is not limited thereto. Further, although the figures illustrate the first semiconductor chip having the plurality of through vias, it will be understood that the present inventive concept is not limited thereto. Accordingly, the first semiconductor chip may not include the plurality of through vias.

In example embodiments, the second semiconductor chip 200 may include the first chiplet die 200a, the second chiplet die 200b, and the third chiplet die 200c. For example, each of the first chiplet die 200a, the second chiplet die 200b, and the third chiplet die 200c may be a chiplet. The chiplet may be a semiconductor chip designed by dividing a single chip into functional portions. For example, a processor chip, such as a central processing unit (CPU), may include logic circuitry as well as memory circuitry, such as static random access memory (SRAM). The processor chip may be designed as small chips, that is, chiplets, by dividing a single semiconductor chip into a portion including the logic circuitry and a portion including the memory circuitry. However, it will be appreciated that the present inventive concept is not limited thereto. Thus, each of the first chiplet die 200a, the second chiplet die 200b, and the third chiplet die 200c may be a single semiconductor chip.

In example embodiments, the first chiplet die 200a may include a second substrate 210a having a first surface 212a and a second surface 214a facing away from the first surface 212a, a second wiring layer 220a provided on the first surface 212a of the second substrate 210a, and a plurality of first chip pads 230a provided on the second wiring layer 220a. The first chiplet die 200a may further include a plurality of first conductive connection members 240a provided on each of the plurality of first chip pads 230a. For example, the plurality of first conductive connection members may include a conductive metallic material.

For example, the first chiplet die may include a logic chip including a logic circuit. Alternatively, the first chiplet die may include a volatile memory device, such as a DRAM, or a non-volatile memory device, such as a NAND flash memory.

The second substrate 210a may have a first surface 212a as an active surface and a second surface 214a as an inactive surface. The first surface and the second surface may extend in the first horizontal direction HD1 and the second horizontal direction HD2 perpendicular to the first horizontal direction HD1, respectively. The second substrate 210 may have a first side portion S21a and a second side portion S22a extending in the first horizontal direction HD1, and a third side portion S23a and a fourth side portion S24a extending in the second horizontal direction HD2. For example, the second substrate may have a square shape when viewed in plan view. The second substrate may include silicon (Si).

The second wiring layer 220a may include a plurality of second wirings 223a and an insulation layer covering the plurality of second wirings 223a.

The plurality of first chip pads 230a may be electrically connected to the plurality of second wirings 223a. The plurality of first chip pads 230a may be provided on the second wiring layer 220a such that the plurality of first chip pads 230a are arranged in the first horizontal direction HD1 and the second horizontal direction HD2, respectively. For example, the plurality of first chip pads may include a conductive metallic material.

The first chiplet die 200a may be mounted on the first semiconductor chip 100 via the plurality of first conductive connection members 240a provided between the plurality of first chip pads 230a and a portion of the plurality of first pads 130, respectively, such that the second wiring layer 220a of the first chiplet die 200a faces the first semiconductor chip 100. For example, the first chiplet die 200a may be disposed adjacent to a third side portion S3 of the first substrate 110.

In example embodiments, the second chiplet die 200b may include a third substrate 210b having a first surface 212b and a second surface 214b facing away from the first surface 212b, a third wiring layer 220b provided on the first surface 212b of the third substrate 210b, and a plurality of second chip pads 230b provided on the third wiring layer 220b. The second chiplet die 200b may further include a plurality of second conductive connection members 240b respectively provided on the plurality of second chip pads 230b. For example, the plurality of second conductive connection members may include a conductive metallic material.

For example, the second chiplet die may include a logic chip including logic circuitry. Alternatively, the semiconductor chip may include a volatile memory device, such as a DRAM, or a non-volatile memory device, such as a NAND flash memory.

The third substrate 210b may have a first surface 212b as an active surface and a second surface 214b as an inactive surface. The first surface and the second surface may extend in the first horizontal direction HD1 and the second horizontal direction HD2 perpendicular to the first horizontal direction HD1, respectively. The third substrate 210b may have a first side portion S21b and a second side portion S22b extending in the first horizontal direction HD1, and a third side portion S23b and a fourth side portion S24b extending in the second horizontal direction HD2. For example, the third substrate may have a square shape when viewed in plan view. The third substrate may include silicon (Si).

The third wiring layer 220b may include a plurality of third wirings 223b and an insulation layer covering the plurality of third wirings 223b.

The plurality of second chip pads 230b may be electrically connected to the plurality of third wirings 223b. The plurality of second chip pads 230b may be provided on the third wiring layer 220b such that the plurality of second chip pads 230b are arranged in the first horizontal direction HD1 and the second horizontal direction HD2, respectively. For example, the plurality of second chip pads may include a conductive metallic material.

The second chiplet die 200b may be mounted on the first semiconductor chip 100 via the plurality of second conductive connection members 240b respectively provided between the plurality of second chip pads 230b and a portion of the plurality of first pads 130 such that the third wiring layer 220b of the second chiplet die 200b faces the first semiconductor chip 100. For example, the second chiplet die 200b may be disposed in a central region of the first substrate 110.

The second chiplet die 200b may be mounted on the first semiconductor chip 100 such that the second chiplet die 200b is spaced apart from the first chiplet die 200a in the first horizontal direction HD1. For example, the second chiplet die 200b may be mounted on the first semiconductor chip 100 to form a first gap G1 in the first horizontal direction HD1 between the second chiplet die 200b and the first chiplet die 200a. The first gap G1 may be provided between the fourth side portion S24a of the first chiplet die 200a and the third side portion S24b of the second chiplet die 200b.

In example embodiments, the third chiplet die 200c may include a fourth substrate 210c having a first surface 212c and a second surface 214c facing away from the first surface 212c, a fourth wiring layer 220c provided on the first surface 212c of the fourth substrate 210c, and a plurality of third chip pads 230c provided on the fourth wiring layer 220c. The third chiplet die 200c may further include a plurality of third conductive connection members 240c respectively provided on the plurality of third chip pads 230c. For example, the plurality of third conductive connection members may include a conductive metallic material.

For example, the third chiplet die may include a logic chip including a logic circuit. Alternatively, the third chiplet die may include a volatile memory device, such as DRAM, or a non-volatile memory device, such as NAND flash memory.

The fourth substrate 210c may have a first surface 212c as an active surface and a second surface 214c as an inactive surface. The first surface and the second surface may extend in the first horizontal direction HD1 and the second horizontal direction HD2 perpendicular to the first horizontal direction HD1, respectively. The fourth substrate 210c may have a first side portion S21c and a second side portion S22c extending in the first horizontal direction HD1, and a third side portion S23c and a fourth side portion S24c extending in the second horizontal direction HD2. For example, the fourth substrate may have a square shape when viewed in plan view. The fourth substrate may include silicon (Si).

The fourth wiring layer 220c may include a plurality of fourth wirings 223c and an insulation layer covering the plurality of fourth wirings 223c.

The plurality of third chip pads 230c may be electrically connected to the plurality of fourth wirings 223c. The plurality of third chip pads 230c may be provided on the fourth wiring layer 220c such that the plurality of third chip pads 230c are arranged in the first horizontal direction HD1 and the second horizontal direction HD2, respectively. For example, the plurality of third chip pads may include a conductive metallic material.

Although only a few chip pads are illustrated in the above figures, it will be understood that the number, shape, and arrangement of the chip pads are provided as an example, so the present inventive concept is not limited thereto.

The third chiplet die 200c may be mounted on the first semiconductor chip 100 via the plurality of third conductive connection members 240c respectively provided between the plurality of third chip pads 230c and a portion of the plurality of first pads 130 such that the fourth wiring layer 220c of the third chiplet die 200c faces the first semiconductor chip 100. For example, the third chiplet die 200c may be disposed adjacent to the fourth side portion S4 of the first substrate 110.

The third chiplet die 200c may be mounted on the first semiconductor chip 100 such that the third chiplet die 200c is spaced apart from the first chiplet die 200a and the second chiplet die 200b in the first horizontal direction HD1. For example, the third chiplet die 200c may be mounted on the first semiconductor chip 100 to form a second gap G2 in the first horizontal direction HD1 between the third chiplet die 200c and the second chiplet die 200b. The second gap G2 may be provided between the fourth side portion S24b of the second chiplet die 200b and the third side portion S24c of the third chiplet die 200c.

The first semiconductor chip 100 may have a first thickness T1, and the first chiplet die 200a, the second chiplet die 200b, and the third chiplet die 200c may have a second thickness T2 greater than the first thickness T1.

Distances in a vertical direction VD from the second surface 214a as an upper surface of the first chiplet die 200a, the second surface 214b as an upper surface of the second chiplet die 200b, and the second surface 214c as an upper surface of the third chiplet die 200c to the lower surface 114 of the first semiconductor chip 100 may have a first height H. The first conductive connection member 240a, the second conductive connection member 240b, and the third conductive connection member 240c may be located below an extended centerline CL passing through a center of the first height H.

In example embodiments, the molding member 300 may be provided on the first semiconductor chip 100 to cover the first chiplet die 200a, the second chiplet die 200b, and the third chiplet die 200c. For example, the molding member may include a polymeric compound such as epoxy molding compounds (EMC).

A coefficient of thermal expansion (CTE) of the molding member 300 may be greater than a coefficient of thermal expansion of each of the first semiconductor chip 100, the first chiplet die 200a, the second chiplet die 200b, and the third chiplet die 200c. For example, the first substrate of the first semiconductor chip, the second substrate of the first chiplet die, the third substrate of the second chiplet die, and the fourth substrate of the third chiplet die may include silicon (Si). The coefficient of thermal expansion (CTE) of the molding member 300 may be greater than the coefficient of thermal expansion of the silicon (Si). Therefore, the molding member 300 may shrink relatively more upon cooling compared to the first semiconductor chip 100, the first chiplet die 200a, the second chiplet die 200b, and the third chiplet die 200c.

The molding member 300 may include a first extension portion EL1 that fills the first gap G1 and a second extension portion EL2 that fills the second gap G2.

The first extension portion EL1 may be provided within the first gap G1 to be in contact with the fourth side portion S24a of the first chiplet die 200a and the third side portion S23b of the second chiplet die 200b, respectively. Since the first extension portion EL1 has a relatively high coefficient of thermal expansion (CTE), the first extension portion EL1 can shrink relatively much within the first gap G1, which can generate a force in a direction in which the first chiplet die 200a and the second chiplet die 200b come closer to each other. Thus, the warpage generated in the semiconductor package may be reduced.

The second extension portion EL2 may be provided within the second gap G2 to be in contact with the fourth side portion S24b of the second chiplet die 200b and the third side portion S23c of the third chiplet die 200c, respectively. Since the second extension portion EL2 has a relatively large coefficient of thermal expansion (CTE), the second extension portion EL2 can shrink relatively much within the second gap G2, which can generate a force in a direction in which the second chiplet die 200b and the third chiplet die 200c come to closer to each other. Thus, the warpage generated in the semiconductor package can be reduced.

As illustrated in FIG. 3, the semiconductor package 10 may be mounted on the external device 20.

In example embodiments, the external device 20 may include a package substrate 21 having a first surface 22 and a second surface 24 that face each other, a plurality of substrate pads 25 provided on the first surface 22 of the package substrate 21, and an insulation layer 26 covering the first surface 22 of the package substrate 21 and exposing each of the plurality of substrate pads 25.

The semiconductor package 10 may be mounted on the external device 20 via a plurality of external connection members 160 of the first semiconductor chip 100 provided between the plurality of substrate pads 25 and the plurality of second pads 140 of the first semiconductor chip 100.

Although the figures illustrate a package substrate as an external device, it will be appreciated that the present inventive concept is not limited thereto. Accordingly, the external device may be changed to another electronic device, such as an interposer.

As described above, the semiconductor package 10 includes the first semiconductor chip 100, the first chiplet die 200a mounted on the first semiconductor chip 100, the second chiplet die 200b spaced from the first chiplet die 200a in the first horizontal direction HD1 to form the first gap G1 between the first chiplet die 200a and the first semiconductor chip 100, and the third chiplet die 200c spaced from the second chiplet die 200b in the first horizontal direction HD1 to form the second gap G2 between the second chiplet die 200b and the first semiconductor chip 100. The semiconductor package 10 may further include the molding member 300 provided on the first semiconductor chip 100 to cover the first chiplet die 200a, the second chiplet die 200b, and the third chiplet die 200c.

The molding member 300 may include the first extension portion EL1 that fills the first gap G1 and the second extension portion EL2 that fills the second gap G2. The molding member may include a polymeric compound having a relatively high coefficient of thermal expansion. The thickness of each of the first chiplet die 200a, second chiplet die 200b, and third chiplet die 200c may be greater than the thickness of the first semiconductor chip 100.

Accordingly, each of the extension portions (first extension portion, second extension portion) of the molding members may have a relatively high coefficient of thermal expansion, and thus each of the extension portions of the molding members may shrink relatively much upon cooling compared to the semiconductor chip or the chiplet. Accordingly, each of the extension portions of the molding member may generate a force in the direction in which the first chiplet die 200a, the second chiplet die 200b, and the third chiplet die 200c come closer to each other. Thus, the warpage of the semiconductor package may be reduced.

Hereinafter, a method of manufacturing the semiconductor package 10 in FIG. 1 will be described.

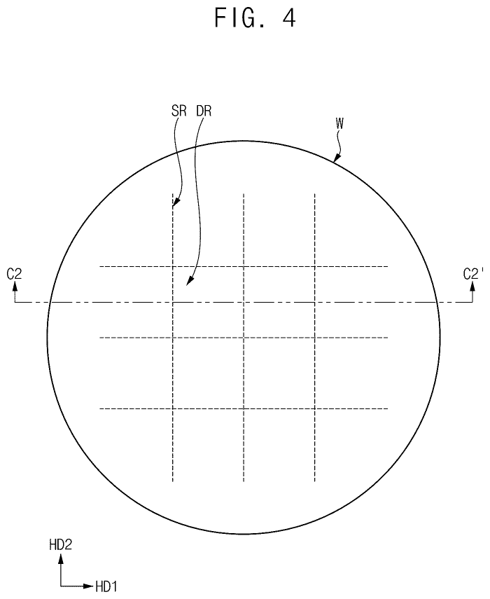

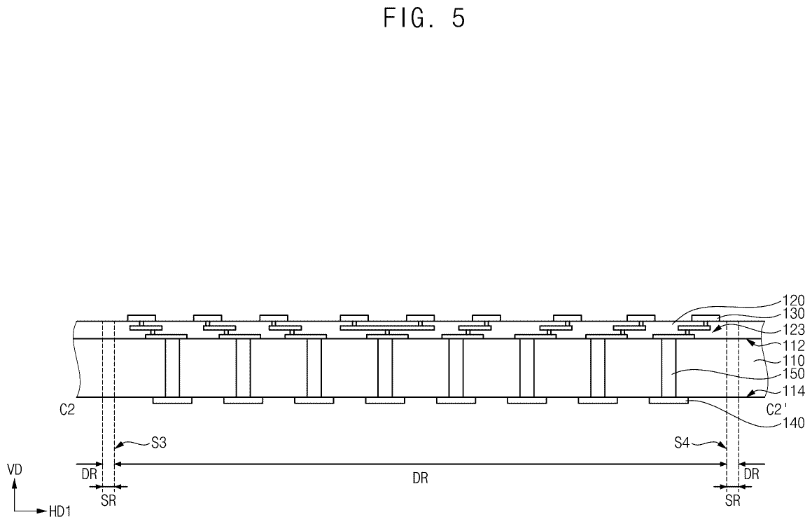

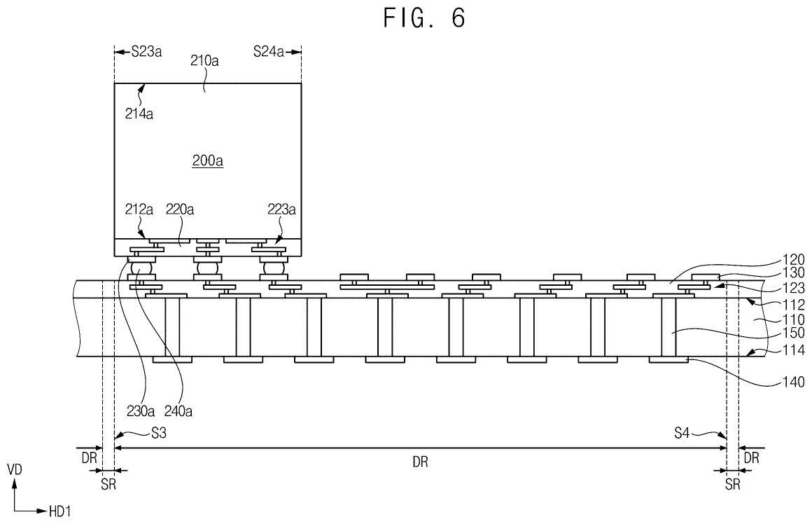

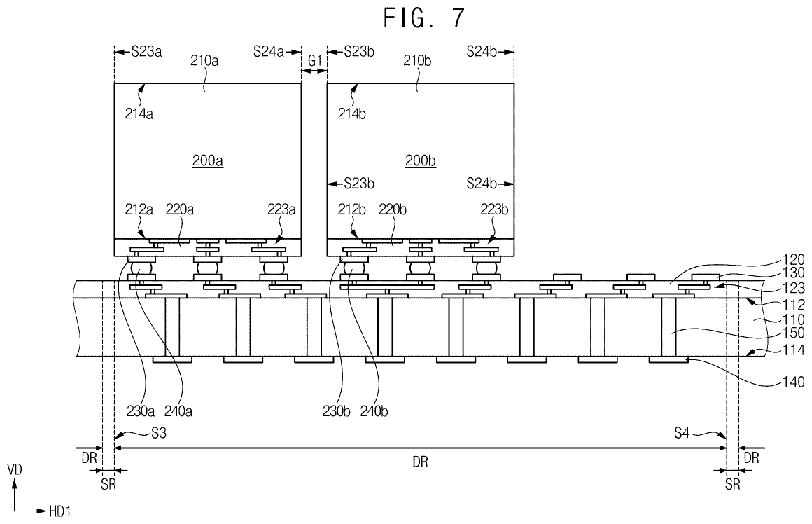

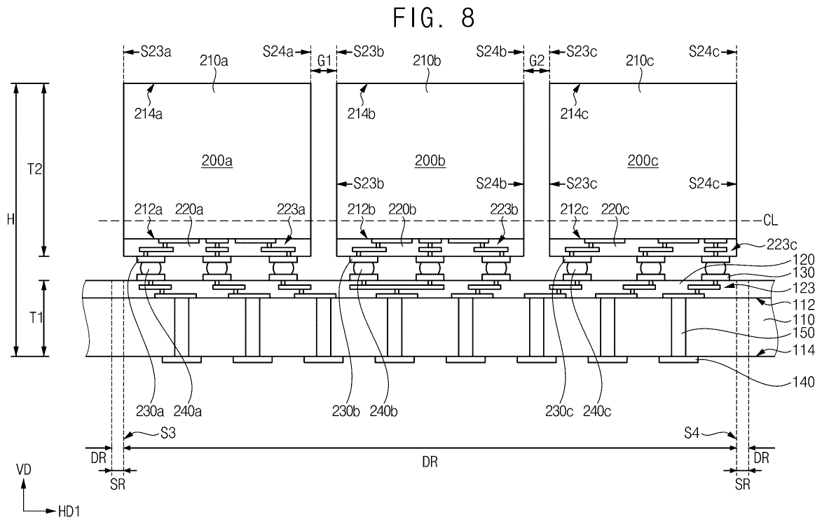

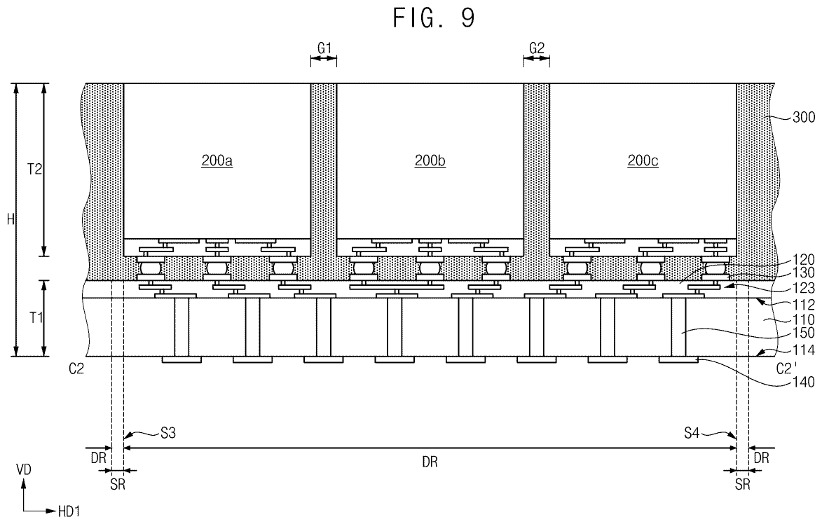

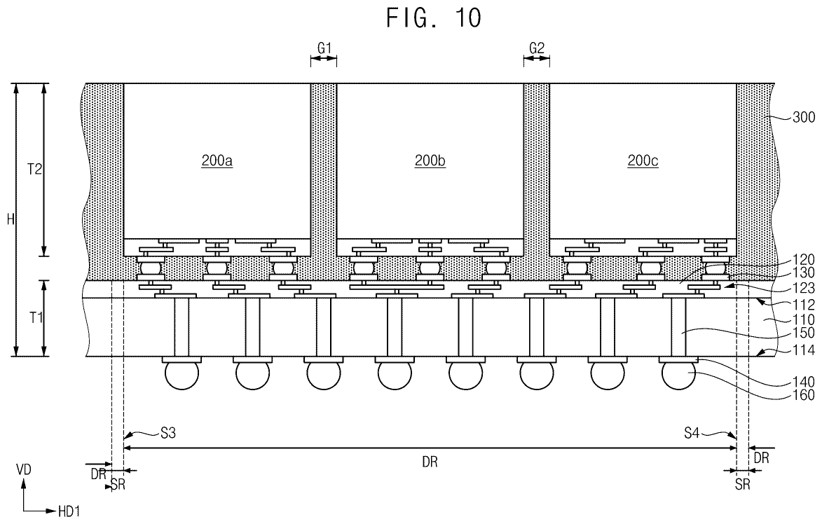

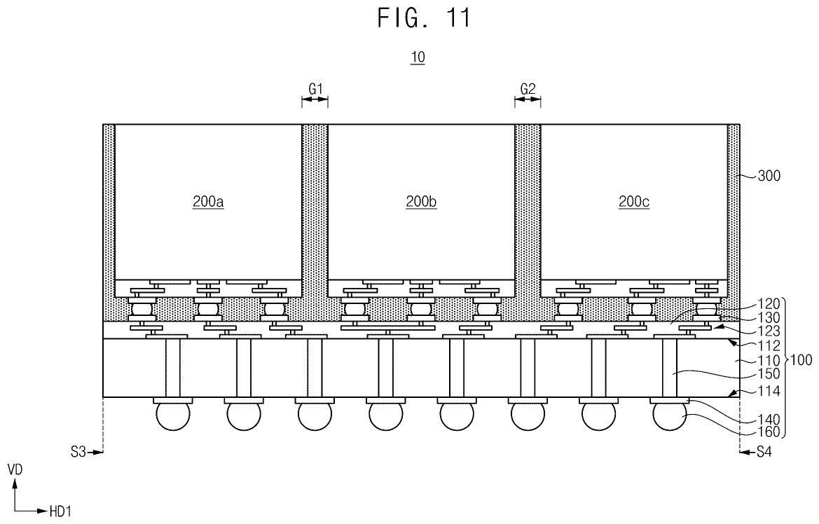

FIG. 4 is a plan view illustrating a wafer in accordance with example embodiments. FIG. 5 is a cross-sectional view taken along the line C2-C2′ in FIG. 4. FIGS. 6 to 8 are cross-sectional views illustrating processes of mounting chiplet dies on the wafer in FIG. 4. FIG. 9 is a cross-sectional view illustrating a process of injecting a molding member to cover the chiplet dies in FIG. 8. FIG. 10 is a cross-sectional view illustrating a process of attaching external connection members to the wafer in FIG. 9. FIG. 11 is a cross-sectional view illustrating a semiconductor package being formed by cutting the wafer in FIG. 10.

Since the semiconductor package manufactured by the manufacturing processes illustrated in FIGS. 4 to 11 is substantially the same as the semiconductor package described in FIGS. 1 to 3, so identical components are denoted by the same reference numerals, and repeated descriptions of identical components are omitted.

Referring to FIGS. 4 and 5, a wafer W may be provided, the wafer including a plurality of die regions DR and a scribe lane region SR surrounding the plurality of die regions. The die regions may be regions individualized by a cutting process to be described later and including first semiconductor chips 100. The scribe lane region may be a region that is removed by the cutting process to be described later.

In example embodiments, the wafer W may include a first substrate 110 having a first surface 112 and a second surface 114 facing away from the first surface 112, a first wiring layer 120 provided on the first surface 112 of the first substrate 110, a plurality of first pads 130 provided on the first wiring layer 120, and a plurality of second pads 140 provided on the second surface 114 of the first substrate 110. The wafer W may further include a plurality of first through vias 150 that penetrate the first substrate 110.

Refer to FIGS. 6 to 8, a first chiplet die 200a, a second chiplet die 200b, and a third chiplet die 200d may be mounted sequentially on the wafer W.

The first chiplet die 200a may be mounted on the wafer W via a plurality of first conductive connection members 240a adjacent to the third side portion S3 of the die region of the wafer W. For example, the first chiplet die 200a may be attached to the wafer W by performing a reflow process. The plurality of first conductive connection members 240a respectively provided between the plurality of first pads 130 and the plurality of first chip pads 230a may be heated to melt and then cooled again to solidify.

In example embodiments, the first chiplet die 200a may include a second substrate 210a having a first surface 212a and a second surface 214a facing away from the first surface 212a, a second wiring layer 220a on the first surface 212a of the second substrate 210a, and a plurality of first chip pads 230a on the second wiring layer 220a. The first chiplet die 200a may further include a plurality of first conductive connection members 240a respectively provided on the plurality of first chip pads 230a.

A second chiplet die 200b may be mounted on the die region of the wafer W to be spaced in a first horizontal direction HD1 from the first chiplet die 200a to form a first gap G1 between the first chiplet die 200a and the second chiplet die 200b. The second chiplet die 200b may be mounted on the wafer W via a plurality of second conductive connection members 240b such that the second chiplet die 200b is located on a center portion of the die region of the wafer W. For example, the second chiplet die 200b may be attached to the wafer W by performing a reflow process. The plurality of second conductive connection members 240b respectively provided between the plurality of second chip pads 230b and the plurality of first pads 130 may be heated to melt and then cooled again to solidify.

In example embodiments, the second chiplet die 200b may include a third substrate 210b having a first surface 212b and a second surface 214b facing away from the first surface 212b, a third wiring layer 220b on the first surface 212b of the third substrate 210b, and a plurality of second chip pads 230b on the third wiring layer 220b. The second chiplet die 200b may further include a plurality of second conductive connection members 240b provided on the plurality of second chip pads 230b.

A third chiplet die 200b may be mounted on the die region of the wafer W to be spaced in a first horizontal direction HD1 from the second chiplet die 200b to form a second gap G2 between the second chiplet die 200b and the third chiplet die 200c. The third chiplet die 200c may be mounted on the wafer W via a plurality of third conductive connection members 240c adjacent to the fourth side portion S4 of the die region of the wafer W. For example, the third chiplet die 200c may be attached to the wafer W by performing a reflow process. The plurality of third conductive connection members 240c respectively provided between the plurality of third chip pads 230c and the plurality of first pads 130 may be heated to melt and then cooled again to solidify.

In example embodiments, the third chiplet die 200c may include a fourth substrate 210c having a first surface 212c and a second surface 214c facing away from the first surface 212c, a fourth wiring layer 220c on the first surface 212c of the fourth substrate 210c, and a plurality of third chip pads 230c on the fourth wiring layer 220c. The third chiplet die 200c may further include a plurality of third conductive connection members 240c provided on the plurality of third chip pads 230c.

Referring to FIG. 9, a molding material in a liquid state may be injected onto the first semiconductor chip 100 to cover the first chiplet die 200a, the second chiplet die 200b, and the third chiplet die 200c, and then the molding material may be cured to form a molding member 300 that fills the first gap G1 and the second gap G2.

The molding material may fill the first gap G1 and the second gap G2. For example, the molding material may include a thermosetting material that hardens when heat is applied. The molding material may include a polymeric compound having a relatively high coefficient of thermal expansion (CTE), such as epoxy molding compounds (EMC). For example, the coefficient of thermal expansion of the molding material may be greater than the coefficient of thermal expansion of silicon (Si).

After that, heat may be applied to the molding material to form a molding member 300 that is cover the first chiplet die 200a, the second chiplet die 200b, and the third chiplet die 200c.

The molding member 300 may then be cooled. At this time, since the molding member 300 has a relatively high coefficient of thermal expansion, the molding member 300 may shrink relatively much upon cooling compared to the first semiconductor chip 100, the first chiplet die 200a, the second chiplet die 200b, and the third chiplet die 200c. Accordingly, the first extension portion EL1 that fills the first gap G1 may generate a force in the direction in which the first chiplet die 200a and the second chiplet die 200b are closer to each other. Furthermore, the second extension portion EL2 that fills the second gap G2 may generate a force in the direction in which the second chiplet die 200b and the third chiplet die 200c are close to each other. Thus, the warpage generated on the wafer W may be reduced.

Referring to FIG. 10, a plurality of external connection members 160 may be attached to the plurality of second pads 140 of the first semiconductor chip 100. For example, the external connection members may be structures configured to electrically connect the semiconductor package 10 to an external device, such as a printed-circuit board (PCB), an interposer, or the like.

Referring to FIG. 11, the wafer W may be separated along the scribe lane region SR, thereby completing the semiconductor package 10.

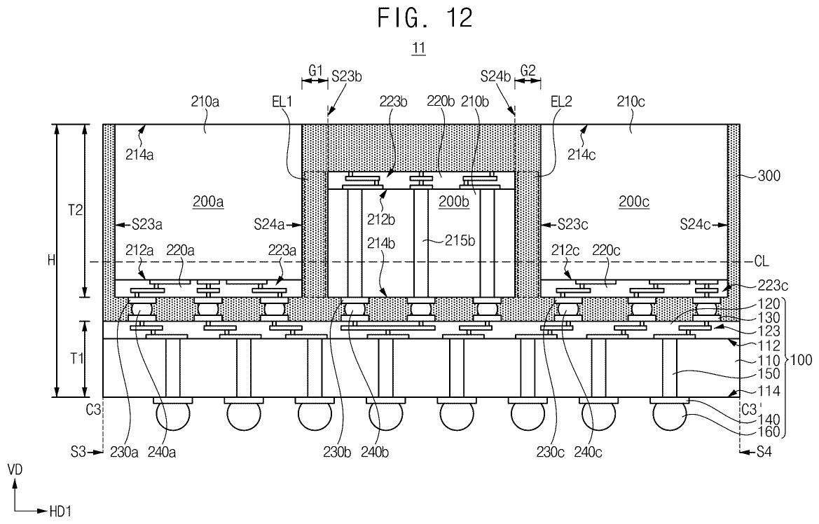

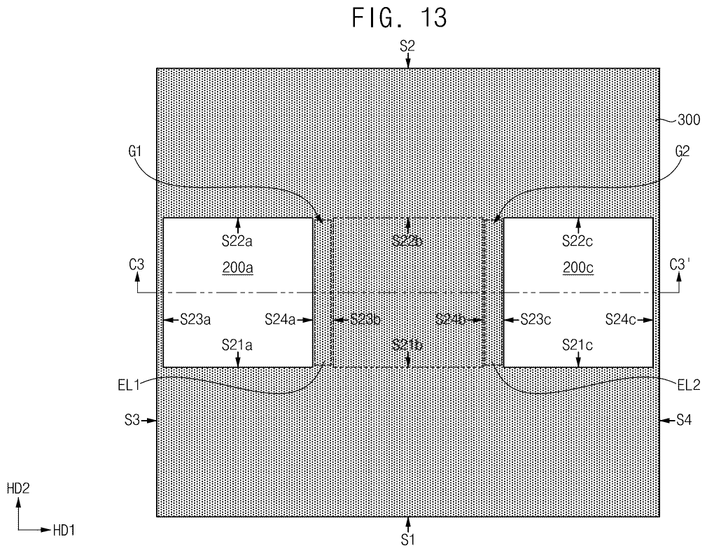

FIG. 12 is a cross-sectional view illustrating a semiconductor package in accordance with example embodiments. FIG. 13 is a plan view illustrating the semiconductor package in FIG. 12. FIG. 12 is a cross-sectional view taken along the line C3-C3′ in FIG. 13.

Since the semiconductor package illustrated in FIGS. 12 and 13 is substantially the same as the semiconductor package described in FIGS. 1 to 3, except for the second chiplet die 200b, so identical components are denoted by the same reference numerals, and repeated descriptions of identical components are omitted.

Referring to FIGS. 12 and 13, a semiconductor package 11 may include a first semiconductor chip 100, a second semiconductor chip 200 including first to third chiplet dies 200a, 200b, 200c mounted on the first semiconductor chip 100, and a molding member 300 provided on the first semiconductor chip 100 to cover the second semiconductor chip 200. The semiconductor package 11 may further include a plurality of external connection members 160 and a plurality of first to third conductive connection members 240a, 240b, 240c.

In example embodiments, the second chiplet die 200b includes a third substrate 210b having a first surface 212b and a second surface 214b facing away from the first surface 212b, a third wiring layer 220b provided on the first surface 212b of the third substrate 210b and including a plurality of third wirings 223b, a plurality of second chip pads 230b provided on the second surface 214b of the third substrate 210b, and a plurality of second through vias 215b penetrating the third substrate 210b. The second chiplet die 200b may further include a plurality of second conductive connection members 240b provided on the plurality of second chip pads 230b.

The third substrate 210b may include a first surface 212b as an active surface and a second surface 214b as an inactive surface. The first surface and the second surface may extend in a first horizontal direction HD1 and a second horizontal direction HD2 perpendicular to the first horizontal direction HD1, respectively.

The third wiring layer 220b may include a plurality of third wirings 223b and an insulation layer covering the plurality of third wirings 223b.

The plurality of second through vias 215b may electrically connect the plurality of second chip pads 230b and the plurality of third wirings 223b. For example, the plurality of second through vias 215b may include a conductive metallic material.

The second chiplet die 200b may be mounted on the first semiconductor chip 100 via the plurality of second conductive connection members 240b respectively provided between the plurality of second chip pads 230b and a portion of the plurality of first pads 130 such that a second surface 214b as an inactive surface of the second chiplet die 200b faces the first semiconductor chip 100.

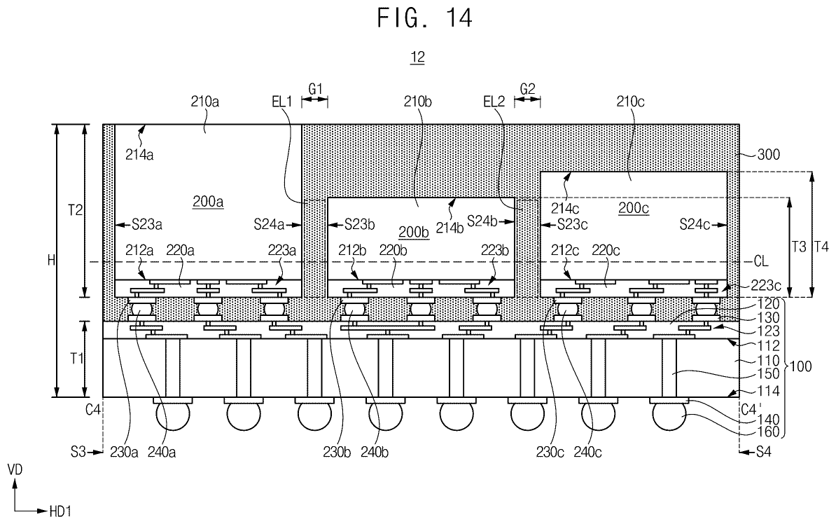

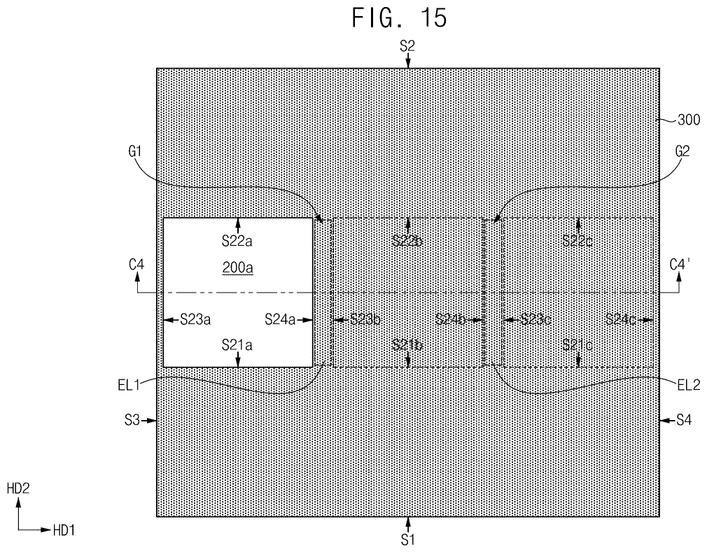

FIG. 14 is a cross-sectional view illustrating a semiconductor package in accordance with example embodiments. FIG. 15 is a plan view illustrating the semiconductor package in FIG. 14. FIG. 14 is a cross-sectional view taken along the line C4-C4′ in FIG. 15.

The semiconductor package illustrated in FIGS. 14 and 15 is substantially the same as the semiconductor package described in FIGS. 1 to 3, except for the second chiplet die 200b and third chiplet die 200c, so identical components are denoted by the same reference numerals, and repeated descriptions of identical components are omitted.

Referring to FIGS. 14 and 15, the semiconductor package 12 may include a first semiconductor chip 100, a second semiconductor chip 200 including first to third chiplet dies 200a, 200b, 200c mounted on the first semiconductor chip 100, and a molding member 300 provided on the first semiconductor chip 100 to cover the second semiconductor chip 200. The semiconductor package 10 may further include a plurality of external connection members 160 and a plurality of first to third conductive connection members 240a, 240b, 240c.

The first semiconductor chip 100 may have a first thickness T1, the first chiplet die 200a may have a second thickness T2, the second chiplet die 200b may have a third thickness T3, and the third chiplet die 200c may have a fourth thickness T4.

At least one of the second thickness T2, third thickness T2, and fourth thickness T4 may be greater than the first thickness T1. For example, the second thickness T2, the third thickness T2, and the fourth thickness T4 may be different from each other.

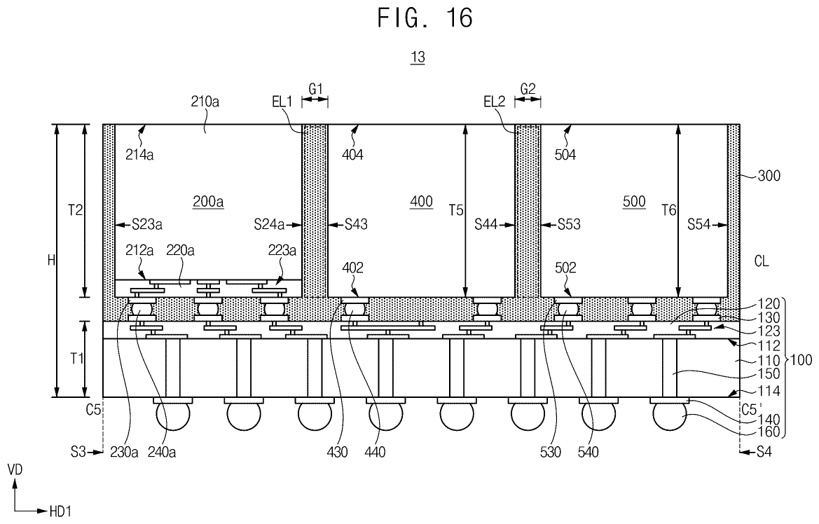

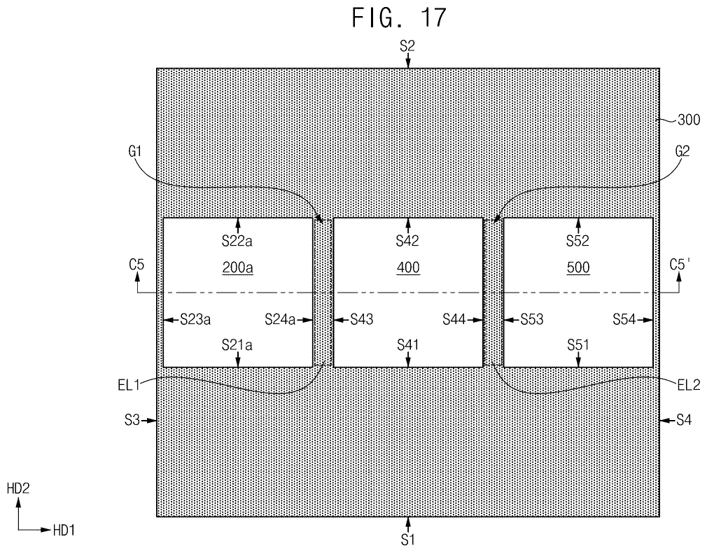

FIG. 16 is a cross-sectional view illustrating a semiconductor package in accordance with example embodiments. FIG. 17 is a plan view illustrating the semiconductor package in FIG. 16. FIG. 16 is a cross-sectional view taken along the lines C5-C5′ in FIG. 17.

The semiconductor package illustrated in FIGS. 16 and 17 is substantially the same as the semiconductor package described in FIGS. 1 to 3, except for the first chip structure 400 and the second chip structure 500, so identical components are denoted by the same reference numerals, and repeated descriptions of identical components are omitted.

Referring to FIGS. 16 and 17, the semiconductor package 13 may include a first semiconductor chip 100, a first chiplet die 200a mounted on the first semiconductor chip 100, and a first chip structure 400 mounted on the first semiconductor chip 100, a second chip structure 500 mounted on the first semiconductor chip 100, and a molding member 300 provided on the first semiconductor chip 100 to cover the first chiplet die 200a, the first chip structure 400, and the second chip structure 500.

In example embodiments, the first chip structure 400 may include a plurality of fourth chip pads 430 and a plurality of fourth conductive connection members 440 provided on the plurality of fourth chip pads 430. For example, the first chip structure may be a passive element (e.g., resistor, capacitor, inductor) and the passive element may be configured to improve the electrical characteristics of a semiconductor package. Alternatively, the first chip structure may be a dummy chip configured to reduce warpage and improve heat dissipation characteristics of the semiconductor package. Alternatively, the first chip structure may be a sensor, such as an image sensor, a gravity sensor, or the like.

The first chip structure 400 may be mounted on the first semiconductor chip 100 via a plurality of fourth conductive connection members 440 respectively provided between the plurality of fourth chip pads 430 and a portion of the plurality of first pads 130. For example, the first chip structure 400 may be disposed in a center portion of the first substrate 110.

The first chip structure 400 may be mounted on the first semiconductor chip 100 such that the first chip structure 400 is spaced apart from the first chiplet die 200a in the first horizontal direction HD1. For example, the first chip structure 400 may be mounted on the first semiconductor chip 100 such that the first chip structure 400 forms a first gap G1 in the first horizontal direction HD1 between the first chip structure 400 and the first chiplet die 200a. The first gap G1 may be provided between a fourth side portion S24a of the first chiplet die 200a and a third side portion S43 of the first chip structure 400.

In example embodiments, the second chip structure 500 may include a plurality of fifth chip pads 530 and a plurality of fifth conductive connection members 540 provided on the plurality of fifth chip pads 530. For example, the second chip structure may be a passive element configured to improve the electrical characteristics of a semiconductor package. Alternatively, the second chip structure may be a dummy chip configured to reduce warpage and improve heat dissipation characteristics of the semiconductor package. Alternatively, the second chip structure may be a sensor, such as an image sensor, gravity sensor, or the like.

The second chip structure 500 may be mounted on the first semiconductor chip 100 via a plurality of fifth conductive connection members 540 respectively provided between a plurality of fifth chip pads 530 and a portion of the plurality of first pads 130. For example, the second chip structure 500 may be disposed adjacent to the fourth side portion S4 of the first substrate 110.

The second chip structure 500 may be mounted on the first semiconductor chip 100 such that the second chip structure 500 is spaced apart from the first chip structure 400 in a first horizontal direction HD1. For example, the second chip structure 500 may be mounted on the first semiconductor chip 100 such that the second chip structure 500 forms a second gap G2 in the first horizontal direction HD1 between the second chip structure 500 and the first chip structure 400. The second gap G2 may be provided between a fourth side portion S44 of the first chip structure 400 and a third side portion S53 of the second chip structure 500.

The first semiconductor chip 100 may have a first thickness T1, the first chiplet die 200a may have a second thickness T2, the first chip structure 400 may have a fourth thickness T4, and the second chip structure 500 may have a fifth thickness T5.

At least one of the second thickness T2, the fourth thickness T4, and the fifth thickness T5 may be greater than the first thickness T1 of the first semiconductor chip 100.

For example, the fourth thickness and the fifth thickness may be the same as the second thickness T2 of the first chiplet die 200a. Alternatively, the fourth thickness and the fifth thickness may be less than or greater than the second thickness T2 of the first chiplet die 200a.

In example embodiments, the molding member 300 may be provided on the first semiconductor chip 100 to cover the first chiplet die 200a, the first chip structure 400, and the second chip structure 500. For example, the molding member may include a polymeric compound such as epoxy molding compounds (EMC).

A coefficient of thermal expansion (CTE) of the molding member 300 may be greater than a coefficient of thermal expansion of each of the first semiconductor chip 100, the first chiplet die 200a, the first chip structure 400, and the second chip structure 500. For example, the first substrate of the first semiconductor chip, the second substrate of the first chiplet die, and the second substrate of the first chiplet die may include silicon (Si). The coefficient of thermal expansion (CTE) of the molding member 300 may be greater than the coefficient of thermal expansion of the silicon (Si). Therefore, the molding member 300 may shrink relatively more upon cooling compared to the first semiconductor chip 100, the first chiplet die 200a, the first chip structure 400, and the second chip structure 500.

The molding member 300 may include a first extension portion EL1 that fills a first gap G1 and a second extension portion EL2 that fills a second gap G2.

The first extension portion EL1 may be provided within the first gap G1 to be in contact with the fourth side portion S24a of the first chiplet die 200a and the third side portion S43 of the first chip structure, respectively. Since the first extension portion EL1 has a relatively high coefficient of thermal expansion (CTE), the first extension portion can shrink relatively much within the first gap G1, thereby generating a force in the direction in which the first chiplet die 200a and the first chip structure 400 are closer to each other. Thus, the warpage generated in the semiconductor package can be reduced.

The second extension portion EL2 may be provided within the second gap G2 to be in contact with the fourth side portion S44 of the first chip structure 400 and the third side portion S53 of the second chip structure 500, respectively. Since the second extension portion EL2 has a relatively high coefficient of thermal expansion (CTE), the second extension portion can shrink relatively much within the second gap G2, thereby generating a force in the direction in which the first chip structure 400 and the second chip structure 500 are closer to each other. Thus, the warpage generated in the semiconductor package can be reduced.

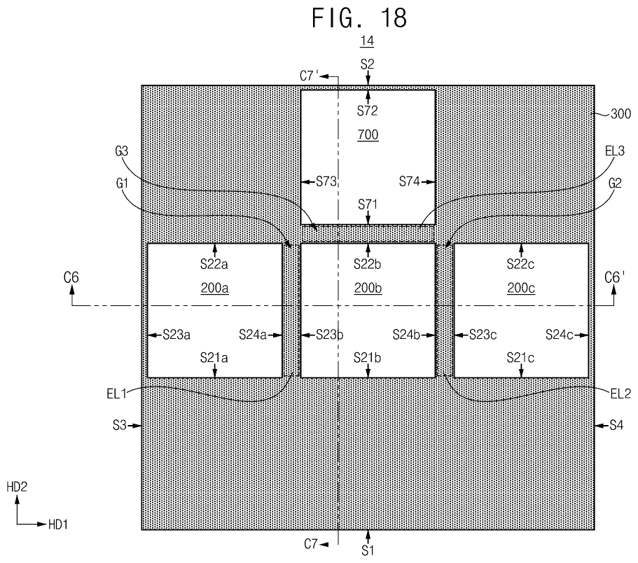

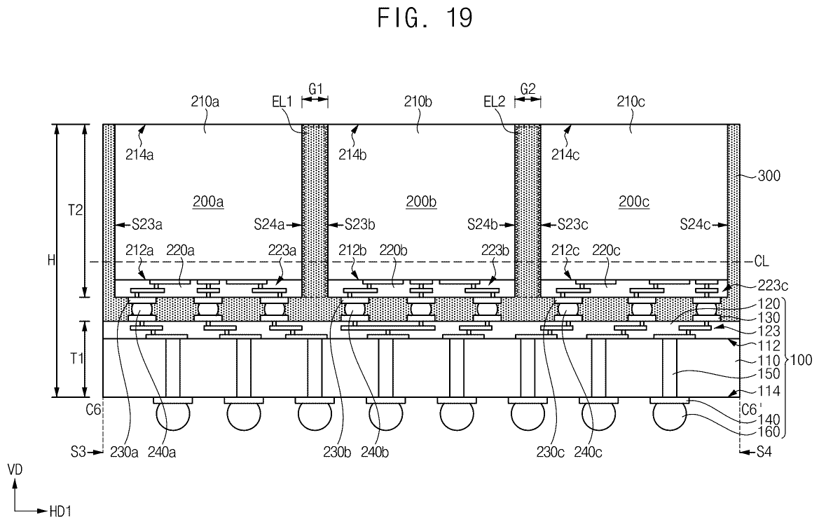

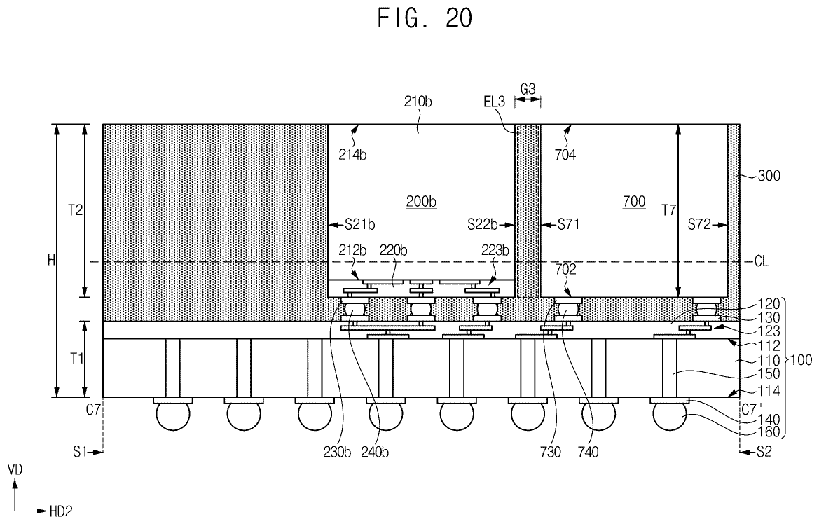

FIG. 18 is a top view illustrating a semiconductor package according to example embodiments. FIG. 19 is a cross-sectional view taken along the line C6-C6′ in FIG. 18. FIG. 20 is a cross-sectional view taken along the line C7-C7′ in FIG. 18.

The semiconductor package illustrated in FIGS. 16 and 17 is substantially the same as the semiconductor package described in FIGS. 1 to 3, with the exception of the third chip structure 700, so identical components are denoted by the same reference numerals, and repeated descriptions of identical components are omitted.

Referring to FIGS. 18 to 20, a semiconductor package 14 may include a first semiconductor chip 100, a second semiconductor chip 200 including first and third chiplet dies 200a, 200b, 200c mounted on the first semiconductor chip 100, a third chip structure 700, and a molding member 300 provided on the first semiconductor chip 100 to cover the first and third chiplet dies 200a, 200b, 200c and the third chip structure 700.

In example embodiments, the third chip structure 700 may include a plurality of sixth chip pads 730 and a plurality of sixth conductive connection members 740 provided on the plurality of sixth chip pads 730. For example, the second chip structure may be a passive element configured to improve the electrical characteristics of a semiconductor package. Alternatively, the third chip structure may be a dummy chip configured to reduce warpage and improve heat dissipation characteristics of the semiconductor package. Alternatively, the third chip structure may be a sensor, such as an image sensor, gravity sensor, or the like.

The third chip structure 700 may be mounted on the first semiconductor chip 100 via a plurality of sixth conductive connection members 740 respectively provided between a plurality of sixth chip pads 730 and a portion of the plurality of first pads 130. For example, the first chip structure 400 may be disposed adjacent to the second side portion S2 of the first substrate 110.

The third chip structure 700 may be mounted on the first semiconductor chip 100 such that the third chip structure 700 is spaced apart from the second chiplet die 200b in a second horizontal direction HD2. For example, the third chip structure 700 may be mounted on the first semiconductor chip 100 such that the third chip structure 700 forms a third gap G3 in the second horizontal direction HD2 between the third chip structure 700 and the second chiplet die 200b. The third gap G3 may be provided between the second side portion S22b of the second chiplet die 200b and the first side portion S71 of the third chip structure 700.

In example embodiments, the molding member 300 may be provided on the first semiconductor chip 100 to cover the first chiplet die 200a, the second chiplet die 200b, the third chiplet die 200c, and the third chip structure 700. For example, the molding member 300 may include a polymeric compound such as epoxy molding compounds (EMC). A coefficient of thermal expansion (CTE) of the molding member 300 may be greater than a coefficient of thermal expansion of each of the first semiconductor chip 100, the first chiplet die 200a, the second chiplet die 200b, the third chiplet die 200c, and the third chip structure 700. For example, the coefficient of thermal expansion (CTE) of the molding member 300 may be greater than the coefficient of thermal expansion of silicon (Si). Therefore, the molding member 300 may shrink relatively more upon cooling compared to the first semiconductor chip 100 to cover the first chiplet die 200a, the second chiplet die 200b, the third chiplet die 200c, and the third chip structure 700.

The molding member 300 may include a first extension portion EL1 that fills a first gap G1, a second extension portion EL2 that fills a second gap G2, and a third extension portion EL3 that fills a third gap G3.

The third extension portion EL3 may be provided within the third gap G3 to be in contact with the second side portion S22b of the second chiplet die 200b and the first side portion S71 of the third chip structure 700, respectively. Since the third extension portion EL3 has a relatively high coefficient of thermal expansion (CTE), the third extension portion may shrink relatively much within the third gap G3, thereby generating a force in the direction in which the second chiplet die 200b and the third chip structure 700 come to closer to each other. Thus, the warpage generated in the semiconductor package can be reduced.

Accordingly, the semiconductor package 14 may be limited and/or prevented from bending in the first horizontal direction HD1 by the first extension portion EL1 and the second extension portion EL2, and the semiconductor package 14 may be limited and/or prevented from bending in the second horizontal direction HD2 by the third extension portion EL3.

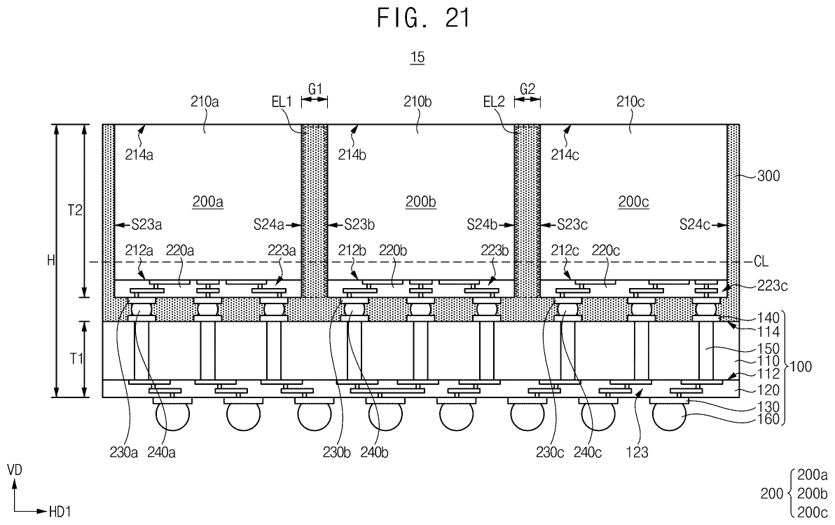

FIG. 21 is a cross-sectional view illustrating a semiconductor package in accordance with example embodiments.

The semiconductor package illustrated in FIG. 21 is substantially the same as the semiconductor package described in FIGS. 1 to 3, with the exception of the first semiconductor chip 100, so that identical components are denoted by the same reference numerals and repeated descriptions of identical components are omitted.

Referring to FIG. 21, the semiconductor package 15 may include a first semiconductor chip 100, a second semiconductor chip 200 mounted on the first semiconductor chip 100, and a molding member 300 provided on the first semiconductor chip 100 to cover the second semiconductor chip 200. The semiconductor package 10 may further include a plurality of external connection members 160 and a plurality of first to third conductive connection members 240a, 240b, 240c.

In example embodiments, the first semiconductor chip 100 may include a first substrate 110 having a first surface 112 and a second surface 114 facing away from the first surface 112, a first wiring layer 120 provided on the first surface 112 of the first substrate 110, a plurality of first pads 130 provided on the first wiring layer 120, and a plurality of second pads 140 provided on the second surface 114 of the first substrate 110. The first semiconductor chip 100 may further include a plurality of first through vias 150 that penetrate the first substrate 110. The first semiconductor chip 100 may further include a plurality of external connection members 160 provided on a plurality of first pads 130.

In example embodiments, the second semiconductor chip 200 may include first to third chiplet dies 200a, 200b and, 200c.

The first chiplet die 200a may include a second substrate 210a having a first surface 212a and a second surface 214a facing away from the first surface 212a, a second wiring layer 220a on the first surface 212a of the second substrate 210a, and a plurality of first chip pads 230a on the second wiring layer 220a. The first chiplet die 200a may further include a plurality of first conductive connection members 240a provided on the plurality of first chip pads 230a.

The second chiplet die 200b may include a third substrate 210b having a first surface 212b and a second surface 214b facing away from the first surface 212b, a third wiring layer 220b provided on the first surface 212b of the third substrate 210b, and a plurality of second chip pads 230b provided on the third wiring layer 220b. The second chiplet die 200b may further include a plurality of second conductive connection members 240b provided on the plurality of second chip pads 230b.

The third chiplet die 200c may include a fourth substrate 210c having a first surface 212c and a second surface 214c facing away from the first surface 212c, a fourth wiring layer 220c provided on the first surface 212c of the fourth substrate 210c, and a plurality of third chip pads 230c provided on the fourth wiring layer 220c. The third chiplet die 200c may further include a plurality of third conductive connection members 240c provided on the plurality of third chip pads 230c.

The first chiplet die 200a may be mounted on the second surface 114 of the first semiconductor chip 100 via the plurality of first conductive connection members 240a such that the first surface 212a of the first chiplet die 200a faces the first semiconductor chip 100.

A second chiplet die 200b may be mounted on the second surface 114 of the first semiconductor chip 100 via a plurality of second conductive connection members 240b such that the first surface 212b of the second chiplet die 200b faces first semiconductor chip 100.

The third chiplet die 200c may be mounted on the second surface 114 of the first semiconductor chip 100 via the plurality of third conductive connection members 240c such that the first surface 212c of the third chiplet die 200c faces the first semiconductor chip 100.

The package may include semiconductor devices such as logic devices or memory devices. The package may include, for example, logic devices such as a central processing unit (CPU, MPU), application processors (AP), volatile memory devices such as SRAM and DRAM devices, and non-volatile memory devices such as flash memory devices, PRAM, MRAM, and RRAM devices.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of example embodiments of inventive concepts. Accordingly, all such modifications are intended to be included within the scope of example embodiments as defined in the claims.

What is claimed is:

1. A semiconductor package, comprising:
a lower semiconductor chip;
an upper semiconductor chip on the lower semiconductor chip, the upper semiconductor chip having a first chiplet die, a second chiplet die, and a third chiplet die spaced apart from each other in a first horizontal direction; and
a molding member on the lower semiconductor chip and covering the upper semiconductor chip,
wherein a thickness of at least one of the first chiplet die, the second chiplet die, and the third chiplet die is greater than a thickness of the lower semiconductor chip,
wherein a coefficient of thermal expansion of the molding member is greater than a coefficient of thermal expansion of the lower semiconductor chip,
wherein a first extension portion of the molding member fills a first gap between the first chiplet die and the second chiplet die, and
wherein a second extension portion of the molding member fills a second gap between the second chiplet die and the third chiplet die.

2. The semiconductor package of claim 1,
wherein the lower semiconductor chip includes a first substrate and a first wiring layer on a first surface of the first substrate, and a second surface of the first substrate is opposite the first surface of the first substrate,
wherein the first chiplet die includes a second substrate and a second wiring layer on a first surface of the second substrate, the first surface of the second substrate faces the lower semiconductor chip, and a second surface of the second substrate is opposite the first surface of the second substrate,
wherein the second chiplet die includes a third substrate and a third wiring layer on a first surface of the third substrate,
wherein a second surface of the third substrate is opposite the first surface of the third substrate, and
wherein the third chiplet die includes a fourth substrate and a fourth wiring layer on a first surface of the fourth substrate, the first surface of the fourth substrate faces the lower semiconductor chip, and a second surface of the fourth substrate is opposite the first surface of the fourth substrate.

3. The semiconductor package of claim 2,
wherein the first chiplet die is mounted on the lower semiconductor chip such that the first surface of the second substrate faces the first surface of the first substrate of the lower semiconductor chip,
wherein the second chiplet die is mounted on the lower semiconductor chip such that the first surface of the third substrate faces the first surface of the first substrate of the lower semiconductor chip, and
wherein the third chiplet die is mounted on the lower semiconductor chip such that the first surface of the fourth substrate faces the first surface of the first substrate of the lower semiconductor chip.

4. The semiconductor package of claim 2, wherein the first chiplet die is mounted on the lower semiconductor chip such that the first surface of the second substrate faces the first surface of the first substrate of the lower semiconductor chip,
wherein the second chiplet die is mounted on the lower semiconductor chip such that the second surface of the third substrate faces the first surface of the first substrate of the lower semiconductor chip, and
wherein the third chiplet die is mounted on the lower semiconductor chip such that the first surface of the fourth substrate faces the first surface of the first substrate of the lower semiconductor chip.

5. The semiconductor package of claim 1, wherein the first chiplet die has a first thickness, the second chiplet die has a second thickness, and the third chiplet die has a third thickness, and
wherein the first thickness, the second thickness, and the third thickness are equal to each other.

6. The semiconductor package of claim 1,
wherein the first chiplet die has a first thickness, the second chiplet die has a second thickness, and the third chiplet die has a third thickness, and
wherein the second thickness and the third thickness are less than the first thickness.

7. The semiconductor package of claim 1, wherein the first extension portion is in contact with a second side surface of the first chiplet die and a first side surface of the second chiplet die, respectively.

8. The semiconductor package of claim 1, wherein the second extension portion is in contact with a second side surface of the second chiplet die and a first side surface of the third chiplet die, respectively.

9. A semiconductor package, comprising:
a first semiconductor chip including a first substrate and a first wiring layer on the first substrate;
a second semiconductor chip including a first chiplet die mounted on the first semiconductor chip via a plurality of first conductive connection members, a second chiplet die mounted on the first semiconductor chip via a plurality of second conductive connection members, and a third chiplet die mounted on the first semiconductor chip via a plurality of third conductive connection members, wherein the first chiplet die, the second chiplet die, and the third chiplet die are spaced apart from each other in a first horizontal direction to define a first gap between the first chiplet die and the second chiplet die and to define a second gap between the second chiplet die and the third chiplet die; and
a molding member on the first semiconductor chip and covering the first chiplet die, the second chiplet die, and the third chiplet die,
wherein a distance in a vertical direction between a lower surface of the first substrate and a highest one of an upper surface of the first chiplet die, an upper surface of the second chiplet die and an upper surface of the third chiplet die has a first height,
wherein the plurality of first conductive connection members, the plurality of second conductive connection members, and the plurality of third conductive connection members are below a central extension line passing through a center of the first height,
wherein a coefficient of thermal expansion of the molding member is greater than a coefficient of thermal expansion of the first semiconductor chip,
wherein a first extension portion of the molding member fills the first gap, and
wherein a second extension portion of the molding member fills the second gap.

10. The semiconductor package of claim 9,
wherein the first chiplet die includes a second substrate and a second wiring layer provided on a first surface of the second substrate, the first surface of the second substrate faces the first semiconductor chip, and a second surface of the second substrate is opposite the first surface of the second substrate,
wherein the second chiplet die includes a third substrate and a third wiring layer on a first surface of the third substrate,
wherein a second surface of the third substrate is opposite the first surface of the third substrate, and
wherein the third chiplet die includes a fourth substrate and a fourth wiring layer on a first surface of the fourth substrate, the first surface of the fourth substrate faces the first semiconductor chip, and a second surface of the fourth substrate is opposite the first surface of the fourth substrate.

11. The semiconductor package of claim 10,
wherein the first chiplet die is mounted on the first semiconductor chip such that the first surface of the second substrate faces the first wiring layer of the first semiconductor chip,
wherein the second chiplet die is mounted on the first semiconductor chip such that the first surface of the third substrate faces the first wiring layer of the first semiconductor chip, and
wherein the third chiplet die is mounted on the first semiconductor chip such that the first surface of the fourth substrate faces the first wiring layer of the first semiconductor chip.

12. The semiconductor package of claim 10,
wherein the first chiplet die is mounted on the first semiconductor chip such that the first surface of the second substrate faces the first wiring layer of the first semiconductor chip,
wherein the second chiplet die is mounted on the first semiconductor chip such that the second surface of the third substrate faces the first wiring layer of the first semiconductor chip, and
wherein the third chiplet die is mounted on the first semiconductor chip such that the first surface of the fourth substrate faces the first wiring layer of the first semiconductor chip.

13. The semiconductor package of claim 9,
wherein the first chiplet die has a first thickness, the second chiplet die has a second thickness, and the third chiplet die has a third thickness,
wherein the first thickness, the second thickness, and the third thickness are equal to each other.

14. The semiconductor package of claim 9,
wherein the first chiplet die has a first thickness, the second chiplet die has a second thickness, and the third chiplet die has a third thickness,
wherein the second thickness and the third thickness are less than the first thickness.

15. The semiconductor package of claim 9, wherein the first extension portion is in contact with a surface of the first chiplet die and a surface of the second chiplet die, respectively.

16. The semiconductor package of claim 9, wherein the second extension portion is in contact with a surface of the second chiplet die and a surface of the third chiplet die, respectively.

17. A semiconductor package, comprising:
a first semiconductor chip;
at least one chiplet die mounted on the first semiconductor chip;
a first chip structure on the first semiconductor chip, the first chip structure being spaced apart from the at least one chiplet die in a first horizontal direction to define a first gap between the first chip structure and the at least one chiplet die;
a second chip structure on the first semiconductor chip, the second chip structure being spaced apart from the at least one chiplet die and the first chip structure in the first horizontal direction to define a second gap between the second chip structure and the first chip structure; and
a molding member on the first semiconductor chip and covering the at least one chiplet die, the first chip structure, and the second chip structure,
wherein a thickness of at least one of the at least one chiplet die, the first chip structure, and the second chip structure is greater than a thickness of the first semiconductor chip;
wherein a coefficient of thermal expansion of the molding member is greater than a coefficient of thermal expansion of the first semiconductor chip,
wherein a first extension portion of the molding member fills the first gap, and
wherein a second extension portion of the molding member fills the second gap.

18. The semiconductor package of claim 17, wherein at least one of the first chip structure and the second chip structure is a passive element.

19. The semiconductor package of claim 17, wherein at least one of the first chip structure and the second chip structure is a dummy chip configured to prevent warpage of the semiconductor package.

20. The semiconductor package of claim 17,
wherein the first extension portion is in contact with a surface of the at least one chiplet die and a first surface of the first chip structure, respectively, and
wherein the second extension portion is in contact with a second surface of the first chip structure and a surface of the second chip structure, respectively.
